(19) United States
(12) Patent Application Publication
(10) Pub. No.: US 2010/0252300 A1
(43) Pub. Date: Oct. 7, 2010

(54) Electromagnetically Shielded Subsea Power Cable

(75) Inventors: Peter J. Worman, Katy, TX (US); Luciana Abib, Lynn Haven, FL (US); Rosianita Balena, Rio de Janeiro (BR); Sean Derrickson, Sugar Land, TX (US)

Correspondence Address: DUANE MORRIS LLP - Houston, 1330 POST OAK BLVD., SUITE 800, HOUSTON, TX, 77056, US

(73) Assignee: OCEANEERING INTERNATIONAL, INC., Houston, TX (US)

(21) Appl. No.: 12/418,934

(22) Filed: Apr. 6, 2009

(51) Int. Cl. H05K 9/00; H01B 7/17

(52) U.S. Cl. 174/103; 174/350

(57) ABSTRACT

This invention is directed to an electromagnetically shielded subsea power cable containing at least one conductor, an electromagnetic shielding layer wrapped around each conductor, an insulation layer wrapped around each electromagnetic shielding layer, and a metallic shielding layer wrapped around each insulation layer. The subsea power cable can be used to transport power from a power source to a power user located subsea or at an intermediate facility, such as a platform.

### FIELD OF THE INVENTION

This invention is directed to an electromagnetically shielded subsea power cable containing at least one conductor, an electromagnetic shielding layer wrapped around each conductor, an insulation layer wrapped around each electromagnetic shielding layer, and a metallic shielding layer wrapped around each insulation layer. The subsea power cable can be used to transport power from a power source to a power consumption device located subsea or at an intermediate facility, such as a platform.

### BACKGROUND OF THE INVENTION

During the transmission of three phase alternating current (“AC”) through subsea power transmission cables, the different phases can interfere with each other, resulting in corrupted voltage waveforms for one or more of the phases. This can result in voltage fluctuations which cause damage to power consumption devices connected to the receiving end of a subsea power transmission cable. Such machines may include subsea pumps.

One or more embodiments of the invention disclosed herein overcome the problem of voltage waveform corruption present in prior art subsea power transmission cables.

### DESCRIPTION OF THE DRAWINGS

FIG. 1 is a radial cross sectional view of a first embodiment of the invention disclosed herein.

FIG. 2 is a longitudinal cross sectional view of a first embodiment of the invention disclosed herein.

FIG. 3 is a radial cross sectional view of a seventh embodiment of the invention disclosed herein.

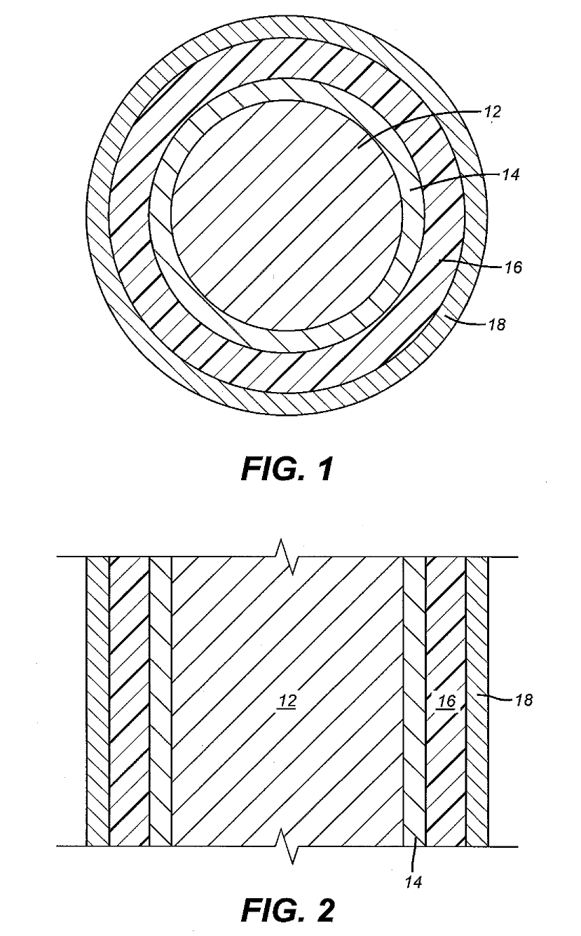

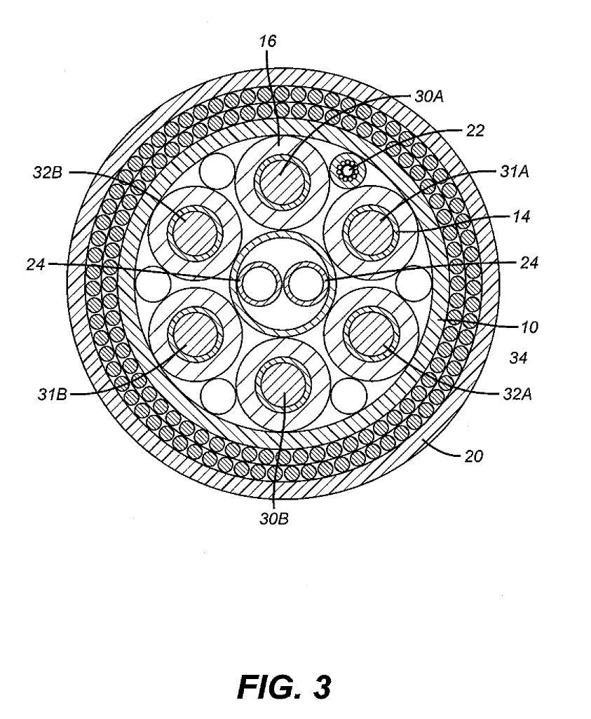

### DESCRIPTION OF THE PREFERRED EMBODIMENTS

In a first preferred embodiment, the invention comprises an inner sheath 10 defining a inner region. In another preferred embodiment, the inner sheath is made from a thermoplastic material.

A first preferred embodiment of the invention further comprises at least one conductor 12 extending within the inner region. In a preferred embodiment, the conductor is made from a material that has a conductivity of at least 3.5×10⁷ siemens/meter. In another preferred embodiment, the conductor comprises copper. In another preferred embodiment, the conductor comprises aluminum. In another preferred embodiment, the conductor comprises direct current. In a single conductor embodiment, the invention is intended for use in seawater having sufficient conductivity to serve as a current return path.

A first preferred embodiment of the invention further comprises an electromagnetic shielding layer 14 directly contacting, and wrapped around, each conductor. In another preferred embodiment, the electromagnetic shielding layer comprises a ferrous material. In another preferred embodiment, the electromagnetic shielding layer comprises stainless steel. In another preferred embodiment, the electromagnetic shielding layer has a magnetic permeability of at least 30×10⁻⁶ Henries per meter.

A first preferred embodiment of the invention further comprises an insulation layer 16 wrapped around each electromagnetic shielding layer. In another preferred embodiment, the insulation layer is made from a thermoplastic material.

A first preferred embodiment of the invention further comprises a metallic shielding layer 18 wrapped around each insulation layer. In another preferred embodiment, the metallic shielding comprises copper.

A second preferred embodiment of the invention comprises all the elements of the first preferred embodiment plus an outer sheath 20 sized and positioned to define an annular region with respect to the inner sheath. In another preferred embodiment, the outer sheath is made from a thermoplastic material.

A third preferred embodiment of the invention comprises all the elements of the first preferred embodiment plus at least one optical cable 22 located in the inner region.

A fourth preferred embodiment of the invention comprises all the elements of the first preferred embodiment plus at least two steel tubes 24 located in the inner region.

A fifth preferred embodiment of the invention comprises all the elements of the first preferred embodiment plus a second conductor extending within the inner region, such that in this embodiment there are at least two conductors extending within the inner region and an electromagnetic shielding layer is wrapped around each copper conductor. In a preferred embodiment, the conductors are made from a material that has a conductivity of at least 3.5×10⁷ siemens/meter. In another preferred embodiment, the conductors comprise copper. In another preferred embodiment, the conductor comprises aluminum. In another preferred embodiment, the conductors of the fifth preferred embodiment comprise single phase alternating current.

A sixth preferred embodiment of the invention comprises all the elements of the fifth preferred embodiment plus a third conductor extending within the inner region, such that in this embodiment there are at least three conductors extending within the inner region and an electromagnetic shielding layer is wrapped around each conductor. The third conductor may exist in the same preferred embodiments as the first and second conductors, described above. In another preferred embodiment, the insulated conductors comprise three phase alternating current. In another preferred embodiment, the insulated conductors have a sufficient size to transmit at least 1000 volts.

A seventh preferred embodiment of the invention comprises all the elements of the fifth preferred embodiment except that in place of at least two conductors 12 extending within the inner region, this seventh preferred embodiment comprises at least three pairs of conductors 30A, 30B, 31A, 31B, 32A, and 32B, extending within the inner region, each pair comprising a first conductor positioned radially opposite a second conductor in the inner region. In a preferred embodiment, the conductors comprise copper. In another preferred embodiment, each pair of conductors carries one of three phases of alternating current.

A eighth preferred embodiment of the invention comprises all the elements of the sixth preferred embodiment plus at least two steel tubes 24 located in the inner region radially interior to each of the conductors.

For each embodiment of the invention described above, the combination of a copper conductor wrapped in an electromagnetic shielding layer, further wrapped in a insulation layer, further wrapped in a metallic shielding layer, as described above is referred to as a “shielded and insulated conductor.” In a ninth preferred embodiment, the invention further comprises an armored sheath 34 encasing all shielded and insulated conductors. In a preferred embodiment, the armored sheath comprises wire.

The foregoing disclosure and description of the inventions are illustrative and explanatory. Various changes in the size, shape, and materials, as well as in the details of the illustrative construction and/or an illustrative method may be made without departing from the spirit of the invention.

What is claimed is:

1. A electromagnetically shielded subsea power cable, comprising:
a. an inner sheath defining a inner region;
b. at least one conductor extending within the inner region;
c. an electromagnetic shielding layer directly contacting, and wrapped around, each conductor;
d. an insulation layer wrapped around each electromagnetic shielding layer; and
e. a metallic shielding layer wrapped around each insulation layer.

2. The power cable of claim 1, further comprising an outer sheath sized and positioned to define an annular region with respect to the inner sheath.

3. The power cable of claim 1, wherein the inner sheath is made from a thermoplastic material.

4. The power cable of claim 1, wherein the electromagnetic shielding layer comprises a ferrous material.

5. The power cable of claim 4, wherein the electromagnetic shielding layer comprises a ferrite based steel.

6. The power cable of claim 1, wherein the metallic shielding comprises copper.

7. The power cable of claim 1, wherein the insulation layer is made from a thermoplastic material.

8. The power cable of claim 1, wherein the conductor comprises copper.

9. The power cable of claim 1, further comprising at least two steel tubes located in the inner region.

10. The power cable of claim 1, wherein the conductor comprises direct current.

11. The power cable of claim 1, further comprising at least two conductors extending within the inner region.

12. The power cable of claim 11, wherein the conductors comprise single phase alternating current.

13. The power cable of claim 1, wherein the electromagnetic shielding layer has a magnetic permeability of at least 30×10⁻⁶ Henries per meter.

14. A electromagnetically shielded subsea power cable, comprising:
a. an inner sheath defining an inner region
b. at least three conductors extending within the inner region;
c. an electromagnetic shielding layer directly contacting, and wrapped around, each conductor;
d. an insulation layer wrapped around each electromagnetic shielding layer; and
e. a metallic shielding layer wrapped around each insulation layer.

15. The power cable of claim 14, wherein the conductors comprise three phase alternating current.

16. The power cable of claim 14, wherein the electromagnetic shielding has a magnetic permeability of at least 30×10⁻⁶ Henries per meter.

17. The power cable of claim 14, wherein the conductors have a sufficient size to transmit at least 1000 volts.

18. The power cable of claim 14, further comprising an armored sheath encasing the conductors, electromagnetic shielding, insulation layer, and metallic shielding layer.

19. The power cable of claim 14, wherein the conductors comprise aluminum.

20. A electromagnetically shielded subsea power cable, comprising:
a. an inner sheath defining an inner region
b. at least three pairs of conductors extending within the inner region, each pair comprising a first conductor positioned radially opposite a second conductor in the inner region;
c. an electromagnetic shielding layer directly contacting, and wrapped around, each conductor;
d. an insulation layer wrapped around each electromagnetic shielding layer; and
e. a metallic shielding layer wrapped around each insulation layer.

21. The power cable of claim 20, wherein each pair of conductors carries one of three phases of alternating current.

22. The power cable of claim 20, further comprising at least two steel tubes located in the inner region radially interior to each of the conductors.
